(19) United States
(12) Patent Application Publication
(10) Pub. No.: US 2025/0015079 A1
(43) Pub. Date: Jan. 9, 2025

(54) SEMICONDUCTOR DEVICE, SEMICONDUCTOR CHIP AND MANUFACTURING METHOD THEREOF

(71) Applicant: Taiwan Semiconductor Manufacturing Company, Ltd., Hsinchu (TW)

(72) Inventors: Ta-Chun LIN, Hsinchu (TW); Huang-Chao Chang, Hsinchu City (TW); Yen-Cheng Lai, Tainan City (TW); Chun-Sheng Liang, Changhua County (TW); Wen-Chiang Hong, Taipei City (TW); Chih-Hao Chang, Hsin-Chu (TW); Jhon Jhy Liaw, Hsinchu County (TW)

(73) Assignee: Taiwan Semiconductor Manufacturing Company, Ltd., Hsinchu (TW)

(21) Appl. No.: 18/346,272

(22) Filed: Jul. 3, 2023

(51) Int. Cl. H01L 27/088; H01L 21/8234; H01L 29/06; H01L 29/417; H01L 29/423; H01L 29/66; H01L 29/775

(52) U.S. Cl. CPC H01L 27/088; H01L 21/823481; H01L 29/0673; H01L 29/41766; H01L 29/41775; H01L 29/42392; H01L 29/66545; H01L 29/775

(57) ABSTRACT

A semiconductor device, a semiconductor chip and manufacturing methods thereof are provided. The semiconductor device includes: channel structures, vertically spaced apart from one another; a gate structure, intersecting the channel structures and wrapping around each of the channel structures; source/drain structures, in lateral contact with the channel structures from opposite sides of the channel structures; and protection structures, separately disposed along a bottom surface of the gate structure, wherein the channel structures are located between the protection structures, and the protection structures comprise a semiconductor material.

### BACKGROUND

Field effect transistors (FETs) are comprehensively used in various integrated circuits. Along with quick development of semiconductor industry, integrated circuits have become more complicated in functionality and faster in operation speed, yet more compact in size. The miniaturization of integrated circuits is mainly resulted from scaling of FETs, which inevitably lead to increase of unwanted parasitic capacitances in FETs. While working with high frequency, FETs may be limited by these parasitic capacitances.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic three-dimensional view illustrating a semiconductor device, according to some embodiments of the present disclosure.

FIG. 1B is a schematic cross-sectional view along a stack of channel structures of the semiconductor device shown in FIG. 1A.

FIG. 1C is a schematic cross-sectional view along a gate structure of the semiconductor device shown in FIG. 1A.

FIG. 1D is a cross-sectional view along the gate structure of the semiconductor device further formed with backside vias, according to some embodiments of the present disclosure.

FIG. 2 is a flow diagram illustrating a process for forming the semiconductor device shown in FIG. 1A, according to some embodiments of the present disclosure.

FIG. 3A through FIG. 3N are schematic three-dimensional views illustrating intermediate structures at various stages of the process shown in FIG. 2.

FIG. 4 is a schematic cross-sectional view along a gate structure of a semiconductor device, according to other embodiments of the present disclosure.

FIG. 5 is a schematic cross-sectional view along a gate structure of a semiconductor device, according to further embodiments of the present disclosure.

FIG. 6 is a schematic cross-sectional view along gate structures of semiconductor devices in a semiconductor chip, according to some embodiments of the present disclosure.

FIG. 7 is a schematic cross-sectional view along gate structures of semiconductor devices in a semiconductor chip, according to other embodiments of the present disclosure.

FIG. 8A through FIG. 8C are schematic cross-sectional views illustrating intermediate structures at some stages during manufacturing of the semiconductor chip as shown in FIG. 7, according to some embodiments of the present disclosure.

FIG. 9A and FIG. 9B are schematic cross-sectional views illustrating intermediate structures at some stages during manufacturing of the semiconductor chip as shown in FIG. 7, according to alternative embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor device and a manufacturing method thereof are provided. The semiconductor device can be a FET, but not limited thereto. According to some embodiments, the semiconductor device is implemented by a gate-all-around (GAA) FET.

The GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

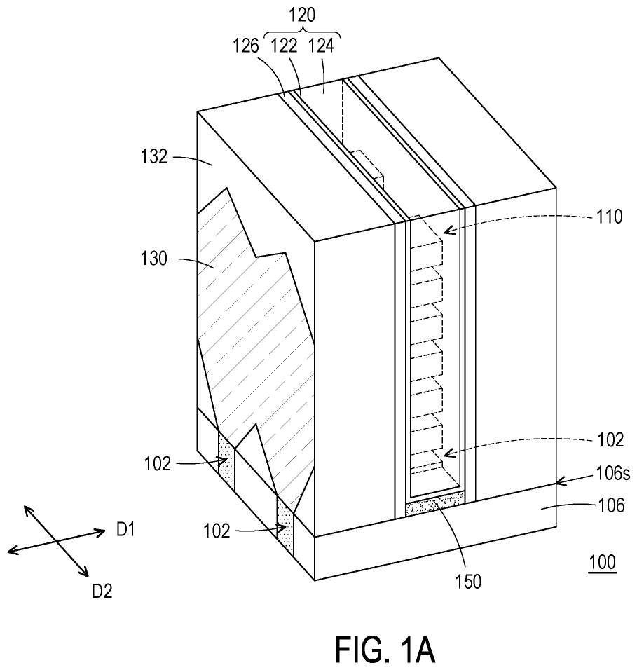

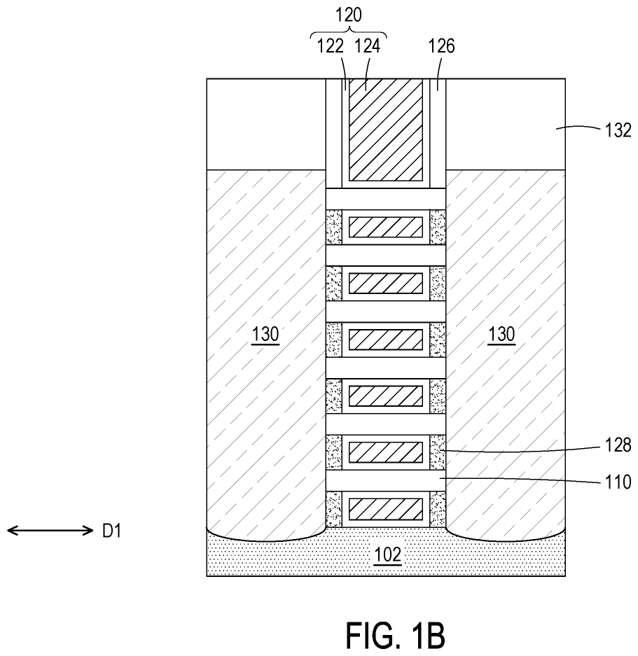

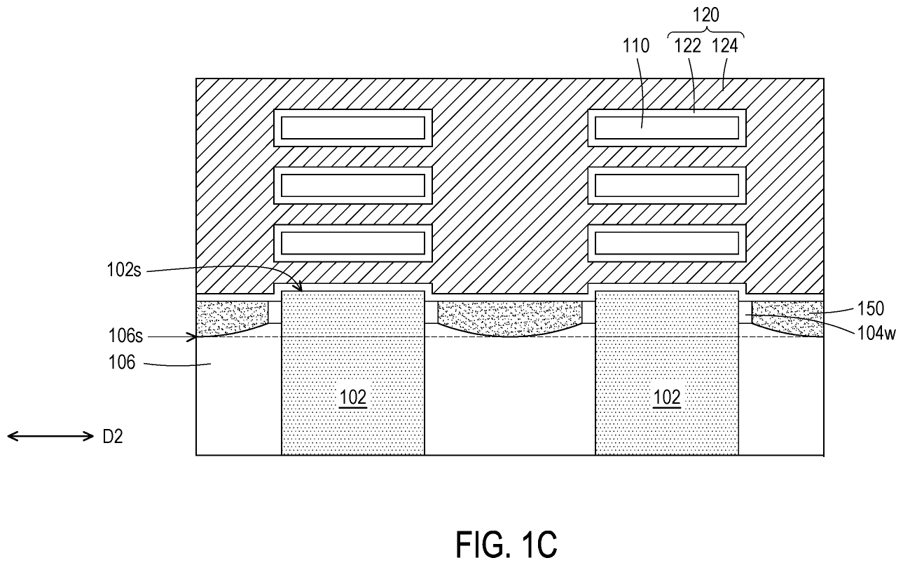

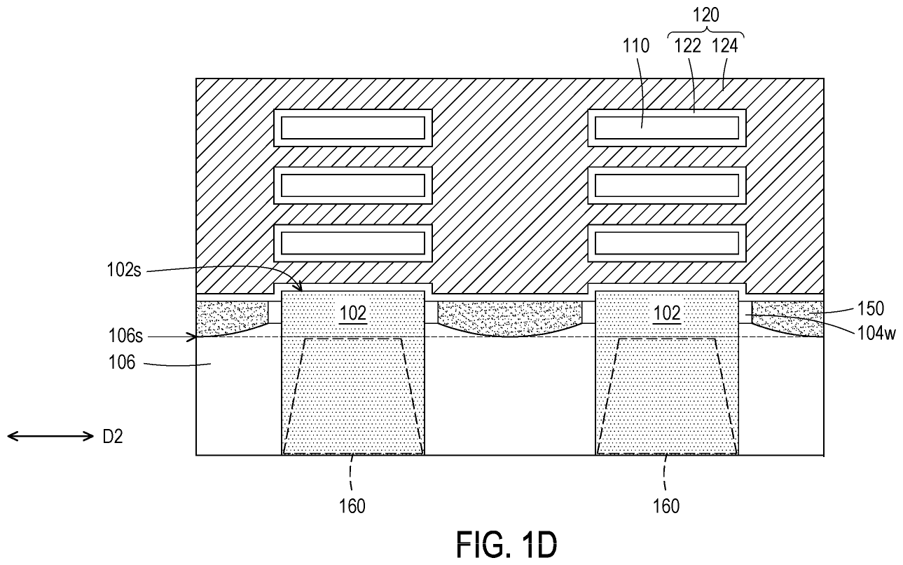

FIG. 1A is a schematic three-dimensional view illustrating a semiconductor device 100, according to some embodiments of the present disclosure. FIG. 1B is a schematic cross-sectional view along a stack of channel structures 110 of the semiconductor device 100 shown in FIG. 1A. FIG. 1C is a schematic cross-sectional view along a gate structure 120 of the semiconductor device 100 shown in FIG. 1A.

Referring to FIG. 1A, the semiconductor device 100 is a GAAFET, which includes channel structures 110 wrapped all around by a gate structure 120. The channel structures 110 are arranged in stacks. In each stack, the channel structures 110 are vertically spaced apart from one another. Therefore, each of the channel structures 110 can be wrapped around by the gate structure 120 intersecting the channel structures 110. In addition, each stack of the channel structures 110 extend over and along a surface fin structure 102 of a semiconductor substrate, and are bounded by opposite ends to a pair of source/drain structures 130 grown from the fin structure 102. A gate terminal of the semiconductor device 100 can be provided by the gate structure 120, and source/drain terminals of the semiconductor device 100 can be provided by the source/drain structures 130.

More specifically, the channel structures 110 may laterally extend along a direction D1, while the gate structure 120 may laterally extend along a direction D2, and intersect the channel structures 110. As the channel structures 110 extend along the fin structures 102, the fin structures 102 may also extend along the direction D1, and intersect with the gate structure 120 from below the gate structure 120. In some embodiments, the channel structures 110 are semiconductor sheets. In other embodiments, the channel structures 110 are semiconductor rods or semiconductor wires. A width of each fin structure 102 along the direction D2 may be close to or substantially identical with a width of the overlying channel structures 110 along the direction D2.

Referring to FIG. 1A and FIG. 1B, the gate structure 120 may include a gate dielectric layer 122 and a gate electrode 124 in contact with the channel structures 110 through the gate dielectric layer 122. The gate dielectric layer 122 wraps around each of the channel structures 110, and may extend along a bottom surface and opposite sidewalls of the gate structure 120. In addition, the gate electrode 124 covers an inner surface of the gate dielectric layer 122, and fills up space enclosed by the gate dielectric layer 122. In some embodiments, the gate electrode 124 is a multilayer structure that may include one or more work function layer(s) and at least one conductive layer covering the work function layer(s). These work function layer(s) and conductive layer(s) may respectively be formed of a metallic material.

In some embodiments, as shown in FIG. 1A, gate spacers 126 cover the opposite sidewalls of the gate electrode 120, to ensure proper separation between the gate structure 120 and the source/drain structures 130. As indicated by FIG. 1B, the gate spacers 126 may respectively have openings through which the channel structure 110 extend to establish contact with the source/drain structures 130. In addition, inner spacers 128 may be filled in these openings, and end portions of each channel structure 110 may respectively be located between vertically adjacent ones of the inner spacers 128. In this way, the gate electrode 120 is separated from the source/drain structures 130 via the gate spacers 126 and the inner spacers 128.

In some embodiments, the source/drain structures 130 are covered by a dielectric layer 132. As a result of a planarization process during manufacturing, a top surface of the dielectric layer 132 may be substantially coplanar with top surfaces of the gate spacers 126 and the gate structure 120. Although not shown, more dielectric layers and interconnections are further formed on the dielectric layer 132 and the gate structure 120, to out-rout the terminals of the semiconductor device 100.

Referring to FIG. 1A and FIG. 1C, a trench isolation structure 106 is formed to isolate the fin structures 102 from one another, and each fin structure 102 may extend in between adjacent portions of the trench isolation structure 106 along the direction D1. In some embodiments, the trench isolation structure 106 is formed of a single insulating material. In alternative embodiments, the trench isolation structure 106 is formed of a combination of different insulating materials. Each insulating material may include silicon oxide, silicon nitride, silicon nitricarbide, silicon oxynitride, silicon oxycarbonitride, silicon oxycarbide, a high-k dielectric material (e.g., hafnium oxide, lanthanum oxide, aluminum oxide) or the like.

The channel structures 110, the gate structure 120 and the source/drain structures 130 are located over the trench isolation structure 106, and so as the gate spacer 126, the inner spacer 128 and the dielectric layer 132. Among these components above the trench isolation structure 106, the gate structure 120 is elevated from the trench isolation structure 106 via protection structures 150, while others of these components are in contact with the trench isolation structure 106 without any of the protection structures 150 in between.

As will be described in further details, the trench isolation structure 106 may be recessed at an early stage of manufacturing, such that a top surface of the trench isolation structure 106 falls to a lowered surface 106s shown in FIG. 1A and FIG. 1C. In order to prevent the trench isolation structure 106 from further recessing during subsequent gate replacement and channel release steps, the protection structures 150 are separately arranged on portions of the trench isolation structure 106 on which the gate structure 102 is disposed. Consequently, the gate structure 120 can be avoided from going further deeper, and undesired capacitive coupling between the gate electrode 124 and the source/drain structures 130 can be effectively lowered. In contrast, if the protection structures 150 are absent, the gate electrode 120 may extend into the trench isolation structure 106 to a level below the surface 106s of the trench isolation structure 106, and the extending portion of the gate structure 120 may capacitively couple to the source/drain structures 130 along skew directions intersected with the directions D1, D2. Such gate-to-source/drain parasitic capacitance may seriously limit operation speed of the semiconductor device 100. In other words, by disposing the protection structures 150, such parasitic capacitance can be effectively lowered, and performance of the semiconductor device 100 can be improved.

As shown in FIG. 1A, the protection structures 150 lying below the gate structure 120 are confined in between the gate spacers 126. On the other hand, the gate spacers 126 as well as the source/drain structures 130 and the dielectric layer 132 at outer sides of the gate spacers 126 are not underlined by any of the protection structures 150.

As shown in FIG. 1C, the fin structures 102 are respectively located in between a pair of the protection structures 150, and the gate dielectric layer 122 of the gate structure 120 covers the fin structures 102 as well as the protection structures 150. The surface 106s of the trench isolation structure 106 lies below top surfaces 102s of the fin structures 102. In some embodiments, the protection structures 150 are disposed on the surface 106s of the trench isolation structure 106, to a height still lower than the top surfaces 102s of the fin structures 102. In these embodiments, the fin structures 102 may slightly protrude with respect to the protection structures 150, and release of the channel structures 110 during manufacturing may not be hindered by the protection structures 150. Further, in some embodiments, the protection structures 150 are in lateral contact with the fin structures 102 via sidewall portions of the dummy gate dielectric layer (referred to as dielectric walls 104w). In these embodiments, the dummy gate dielectric layer is remained as the dielectric walls 104w. In addition, top surfaces of the dielectric walls 104w may be substantially coplanar with top surface of the protection structures 150. However, in other embodiments, the protection structures 150 are in contact with the fin structures 102 without any portion of the dummy gate dielectric layer in between.

According to some embodiments, the protection structures 150 are bottom portions of a dummy gate electrode, and rest portions of the dummy gate electrode are replaced by the gate electrode 124 of the gate structure 120 during manufacturing. In these embodiments, as being part of the dummy gate electrode, the protection structures 150 are formed of a semiconductor material, such as silicon, germanium or silicon germanium. Further, the protection structures 150 may be identical with rest portions of the dummy gate electrode, in terms of material and crystallinity. As an example, the protection structures 150 and rest portions of the dummy gate electrode are both formed of polysilicon. Alternatively, the protection structures 150 may be identical with rest portions of the dummy gate electrode in terms of material, but crystallinity of the protection structures 150 may be lowered than rest portions of the dummy gate electrode. For instance, the protection structures 150 may be formed of amorphous silicon or silicon with rather low crystallinity, while rest portions of the dummy gate electrode may be formed of silicon with rather high crystallinity.

In addition to prevent high parasitic capacitance between the gate electrode 124 and the source/drain structures 130, the protection structures 150 are configured to ensure proper isolation between the gate electrode 124 and possible backside vias extending to the source/drain structures 130 from a back side of the semiconductor substrate.

FIG. 1D is a cross-sectional view along the gate structure 120 of the semiconductor device 100 formed with backside vias 160, according to some embodiments of the present disclosure.

Each fin structure 102 and the overlying stack of channel structures 110 extend along a normal direction of a plane spanning along the direction D2 and a vertical direction (i.e., the cross-section shown in FIG. 1D), and the source/drain structures 130 (not shown in FIG. 1D) are disposed in front of and behind such plane. The backside vias 160 may extend to the source/drain structures 130 from bottom of the fin structures 102, to rout the source/drain terminals of the semiconductor device 100 to a backside of the semiconductor device 100. As the source/drain structures 130 are located in front and behind the cross-section shown in FIG. 1D, the backside vias 160 are also positioned in front and behind the cross-section shown in FIG. 1D, thus are depicted by dash lines.

As shown in FIG. 1D, the backside vias 160 may extend to a height substantially leveled with or slightly higher/lower than the surface 106s of the trench isolation structure 106, so as to establish contact with the source/drain structures 130. As described, the gate structure 120 can be prevented from further extending into the trench isolation structure 106 to a depth below the surface 106s by disposing the protection structures 150. Accordingly, unintended contact between the gate electrode 124 of the gate structure 120 and the backside vias 160 can be avoided. In contrast, if the protection structures 150 are absent, the gate electrode 124 may extend to a depth lower than the surface 106s, and may contact the backside vias 160 particularly when the backside vias 160 are laterally offset with respect to the fin structures 102. Consequently, undesired leakage paths between the gate electrode 124 and the source/drain structures 130 may be established through the backside vias 160. Therefore, by disposing the protection structures 150, it can be ensured that the gate electrode 124 is located above the surface 106s of the trench isolation structure 106, and the backside vias 160 are vertically spaced apart from the gate electrode 124. As a result, unintentional contact between the backside vias 160 and the gate electrode 124 can be effectively avoided.

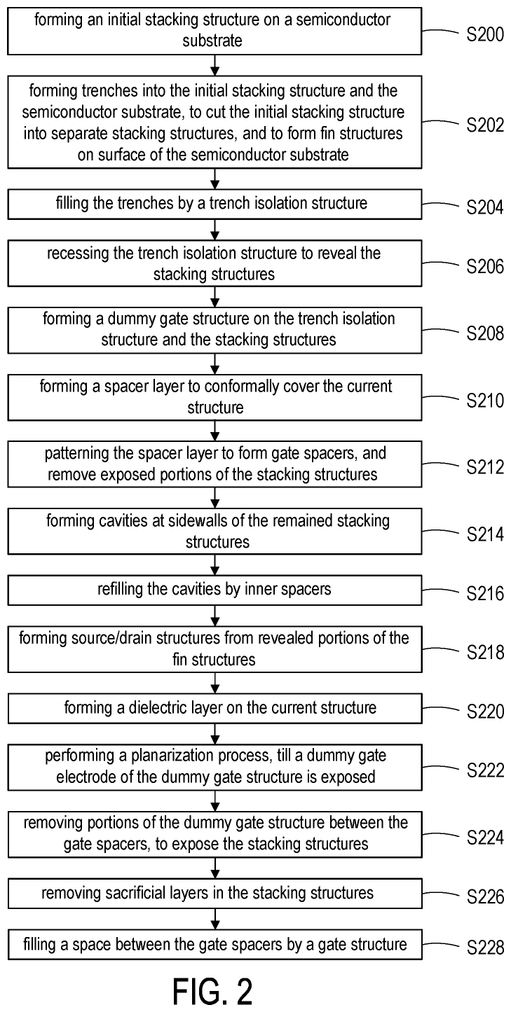

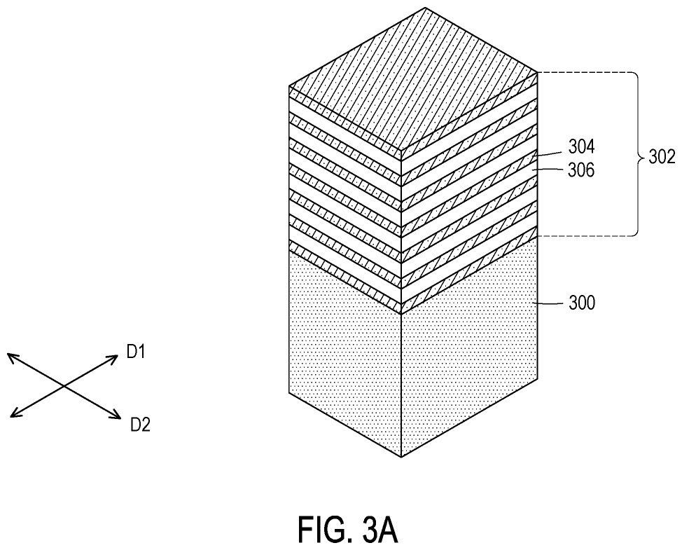

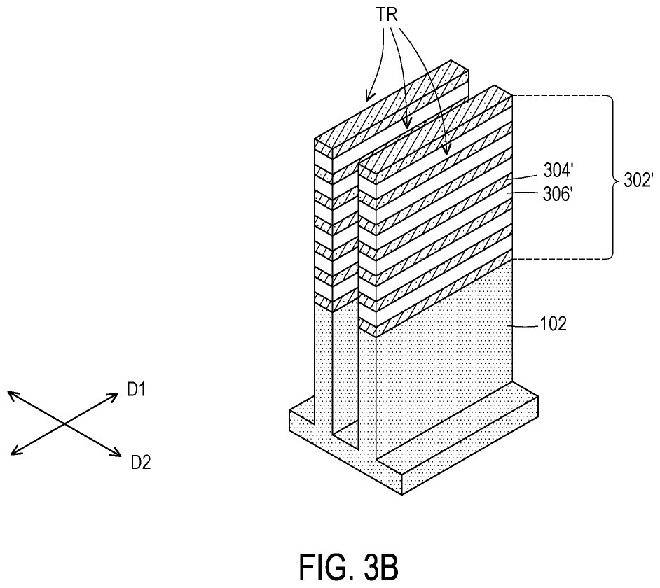

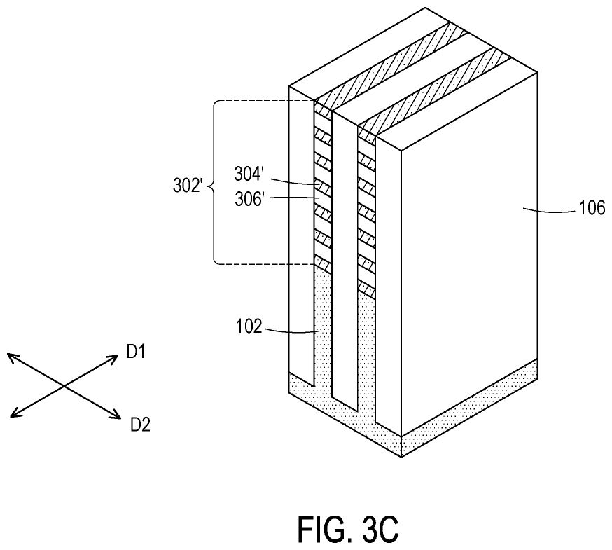

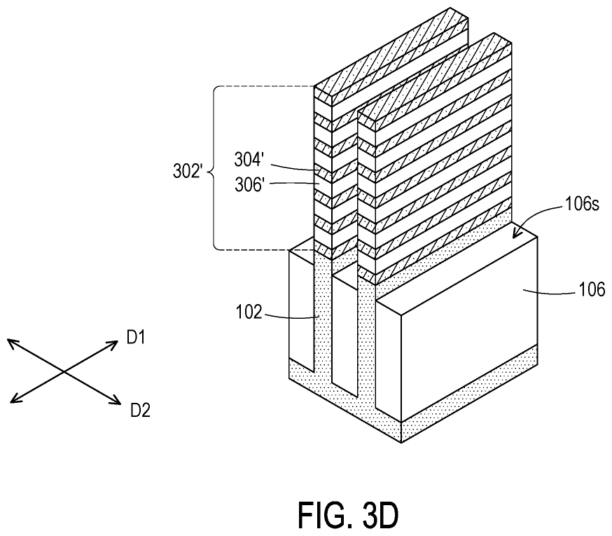

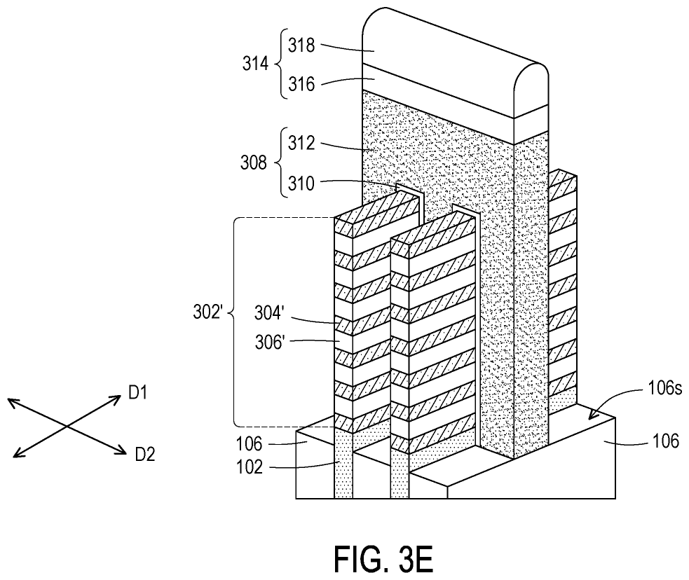

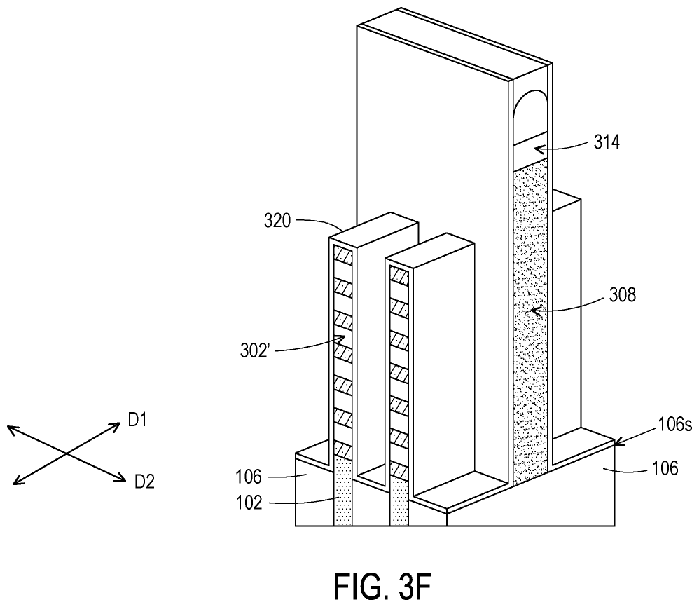

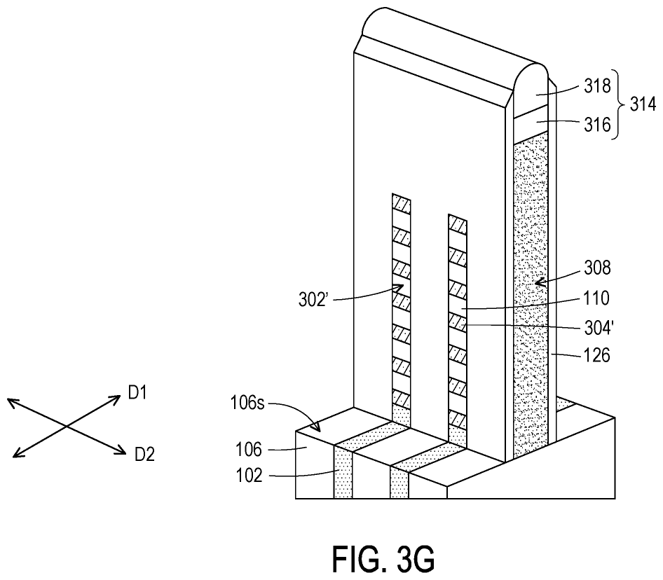

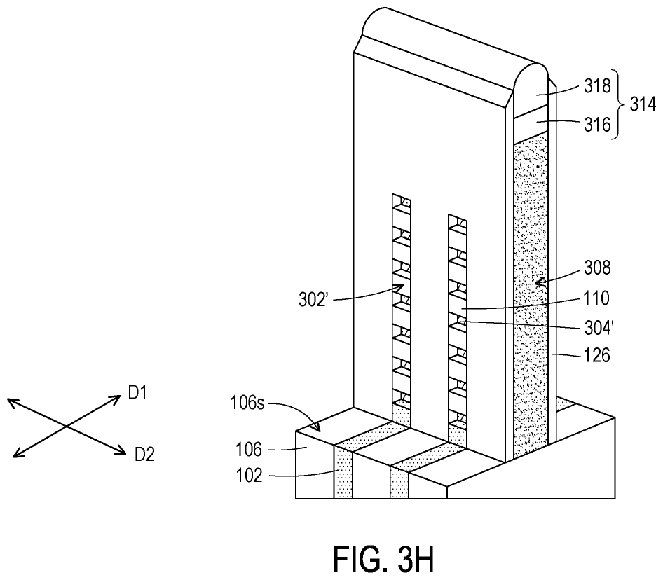

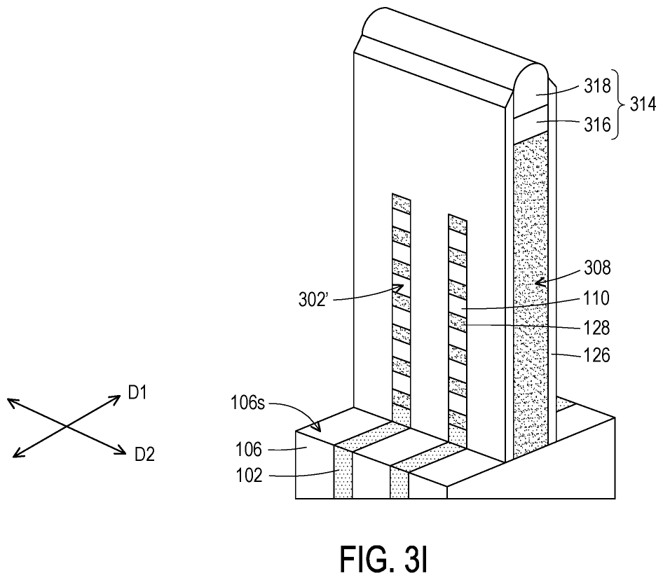

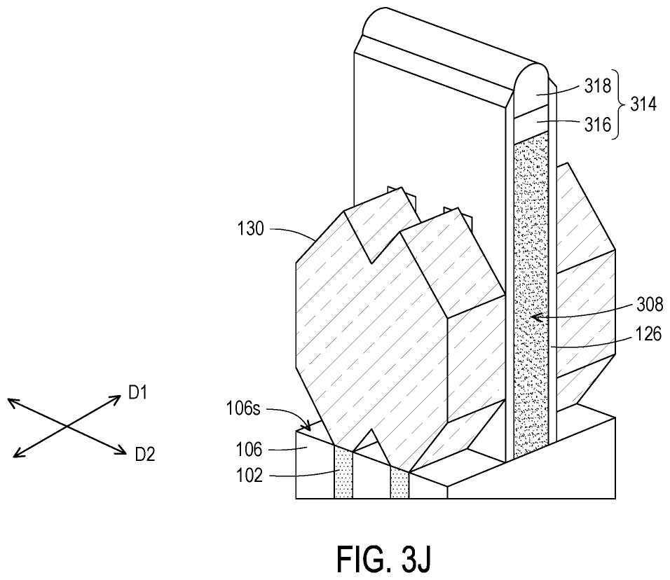

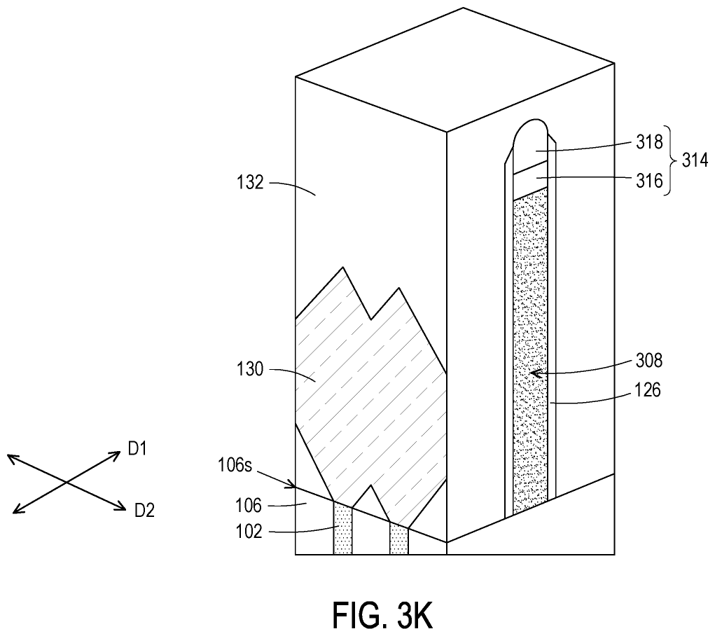

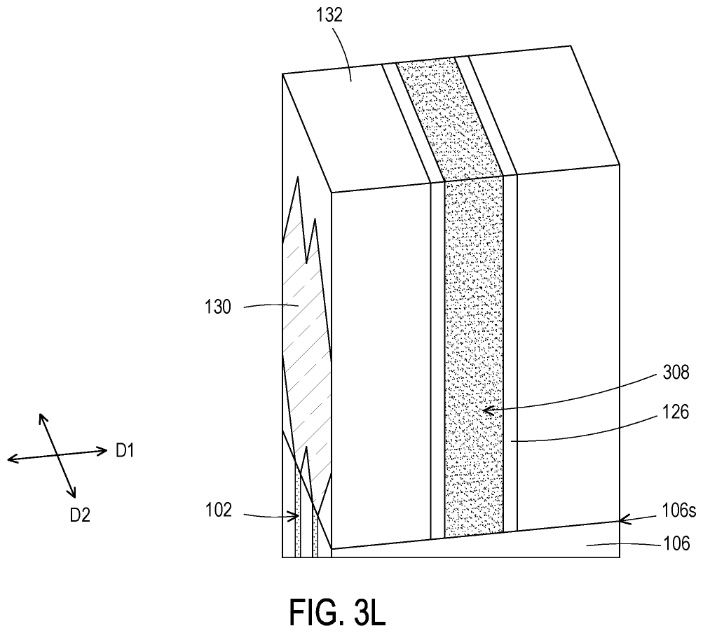

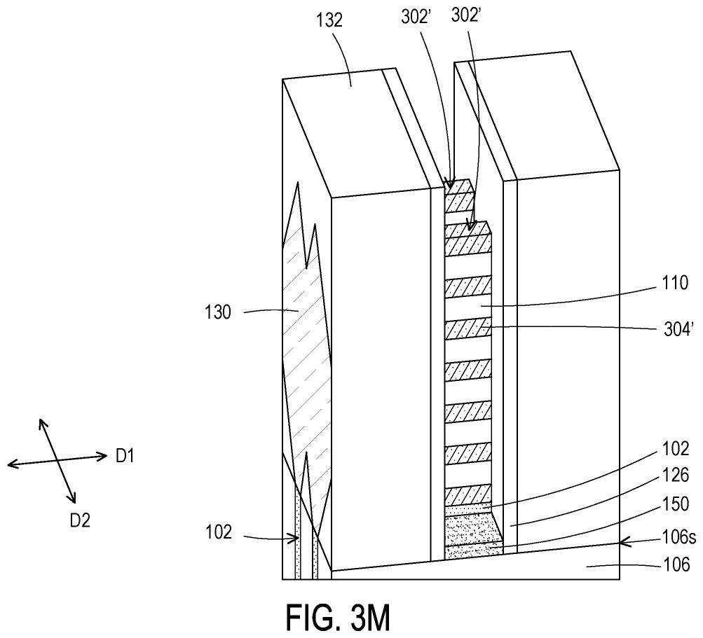

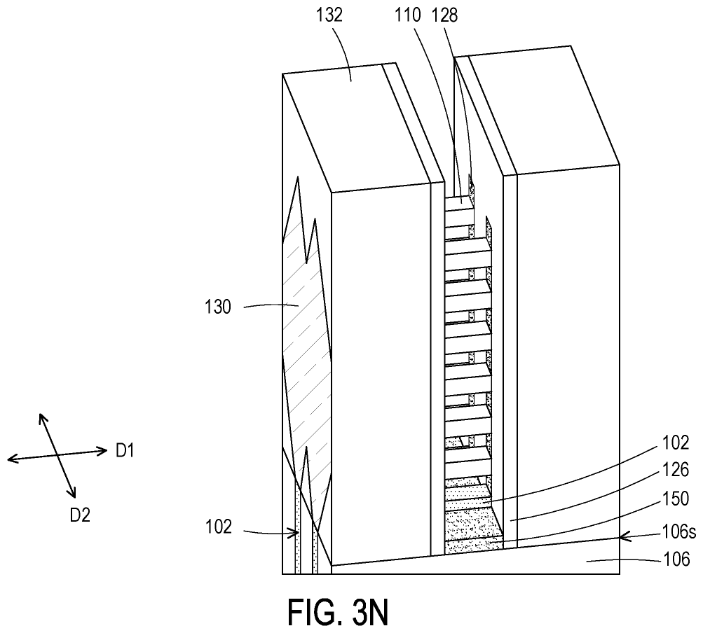

FIG. 2 is a flow diagram illustrating a process for forming the semiconductor device 100, according to some embodiments of the present disclosure. FIG. 3A through FIG. 3N are schematic three-dimensional views illustrating intermediate structures at various stages of the process shown in FIG. 2.

Referring to FIG. 2 and FIG. 3A, at a step S200, a semiconductor substrate 300 is provided and an initial stacking structure 302 is formed on the semiconductor substrate 300. The initial stacking structure 302 includes sacrificial layers 304 and channel layers 306 alternately stacked along a vertical direction. According to some embodiments, the sacrificial layers 304 and the channel layers 306 are formed of different semiconductor materials. As an example (but not limited to), the sacrificial layers 304 are formed of SiGe, whereas the channel layers 306 are formed of Si.

Referring to FIG. 2 and FIG. 3B, at a step S202, trenches TR are formed into the initial stacking structure 302 and the semiconductor substrate 300. As a result, a surface portion of the semiconductor substrate 300 is shaped into the fin structures 102. In addition, the initial stacking structure 302 is patterned into separate stacking structures 302′. Portions of the channel layers 306 are remained in the stacking structures 302′, as channel layers 306′. In addition, portions of the sacrificial layers 304 are remained in the stacking structures 302′, as sacrificial layers 304′.

Referring to FIG. 2 and FIG. 3C, at a step S204, the trenches TR are filled by the trench isolation structure 106. Currently, the trench isolation structure 106 fills up the trenches TR. As a result, the fin structures 102 are laterally spaced apart from one another via lower portions of the trench isolation structure 106. In addition, the stacking structures 302′ are laterally spaced apart from one another via upper portions of the trench isolation structure 106.

Referring to FIG. 2 and FIG. 3D, at a step S206, the trench isolation structure 106 is recessed to reveal the stacking structures 302′. In some embodiments, a top surface of the trench isolation structure 106 may fall to the surface 106s as a result of the recessing. In these embodiments, top portions of the fin structures 102 are also revealed, and protrude with respect to the trench isolation structure 106.

Referring to FIG. 2 and FIG. 3E, at a step S208, a dummy gate structure 308 is formed on the recessed trench isolation structure 106 and the revealed stacking structures 302′. The dummy gate structure 308 intersects the stacking structures 302′, and covers a top surface and opposite sidewalls of each stacking structure 302′. According to some embodiments, the dummy gate structure 308 includes a dummy gate dielectric layer 310 extending along a bottom side of the dummy gate structure 308, and includes a dummy gate electrode 312 in contact with the stacking structures 302′ through the dummy gate dielectric layer 310. As an example, the dummy gate dielectric layer 310 may be formed of silicon oxide, whereas the dummy gate electrode 312 may be formed of silicon, germanium or silicon germanium. As described, bottom portions of the dummy gate electrode 312 may remain to form the protection structures 150, and may be identical with rest portions of the dummy gate electrode 312 in terms of material, but the same as or different from rest portions of the dummy gate electrode 312 in terms of crystallinity. For instance, crystallinity of the bottom portions of the dummy gate electrode 312 for forming the protection structures 150 may be the same or lower than crystallinity of rest portions of the dummy gate electrode 312.

In some embodiments, a hard mask structure 314 is further formed along a top side of the dummy gate structure 308, for patterning of the dummy gate structure 308. In certain cases, the hard mask structure 314 may be a multilayer structure. For instance, the hard mask structure 314 may include a first hard mask layer 316 and a second hard mask layer 318 stacked on the first hard mask layer 316.

Referring to FIG. 2 and FIG. 3F, at a step S210, exposed surfaces of the current structure are conformally covered by a spacer layer 320. That is, exposed surfaces of the trench isolation structure 106, the stacking structures 302′, the dummy gate structure 308 and the hard mask structure 314 are lined with the spacer layer 320.

Referring to FIG. 2 and FIG. 3G, at a step S212, the spacer layer 320 is patterned and exposed portions of the stacking structures 302′ are removed. Specifically, the spacer layer 320 may be entirely removed, except for sidewall portions covering sidewalls of the dummy gate structure 308 and the hard mask structure 314. Such sidewall portions of the spacer layer 320 are remained, and referred to as the gate spacers 126. As the spacer layer 320 is patterned to form the gate spacers 126, portions of the stacking structures 302′ and the trench isolation structure 106 extending outside the gate spacers 126 are exposed, and such portions of the stacking structures 302′ are subjected to removal. Thereby, portions of the fin structures 102 lying below are revealed. In addition, remained stacking structures 302′ are wrapped in the dummy gate structure 308 and the gate spacers 126, with sidewalls exposed. The channel layers 306′ left in the remained stacking structures 302′ are referred to as the channel structures 110. Currently, the channel structures 110 are spaced apart from each other and separated from the fin structures 102 by the remained sacrificial layers 304′.

Referring to FIG. 2 and FIG. 3H, at a step S214, the sacrificial layers 304′ are laterally recessed with respect to the channel structures 110. As a result of such selective recessing, cavities are formed at opposite sidewalls of each stacking structure 302′.

Referring to FIG. 2 and FIG. 3I, at a step S216, these cavities are refilled by the inner spacers 128. As a result, opposite ends of each sacrificial layer 304′ are bounded by a pair of the inner spacers 128. In addition, the channel structures 110 and the inner spacers 128 are revealed at sidewalls of the stacking structures 302′.

Referring to FIG. 2 and FIG. 3J, at a step S218, the source/drain structures 130 are formed from revealed portions of the fin structures 102. In order to ensure that each of the channel structures 110 in the stacking structures 302′ can establish contact with the source/drain structures 130, the source/drain structures 130 may be formed to a height close to or substantially leveled with top surfaces of the stacking structures 302′. An epitaxial growth process may be used for forming the source/drain structures 130, and various approaches may be adopted to control shapes of the source/drain structures 130.

Referring to FIG. 2 and FIG. 3K, at a step S220, the dielectric layer 132 is formed on the current structure. In some embodiments, the dielectric layer 132 is formed from the surface 106s of the trench isolation structure 106, to a height over top surface of the hard mask structure 314, such that the hard mask structure 314, the dummy gate structure 308, the gate spacers 126 and the source/drain structures 130 are entirely embedded in the dielectric layer 132.

Referring to FIG. 2 and FIG. 3L, at a step S222, a planarization process is performed, till the dummy gate electrode 312 is exposed. As a result of the planarization process, the hard mask structure 314 may be entirely removed, and the dielectric layer 132 as well as the gate spacers 126 are recessed.

Referring to FIG. 2 and FIG. 3M, at a step S224, portions of the dummy gate structure 308 between the gate spacers 126 are removed to expose the stacking structures 302′. However, such portions of the dummy gate structure 308 are not entirely removed. Instead, bottom portions of the dummy gate electrode 312 are remained on the surface 106s of the trench isolation structure 106 as the protection structures 150, to prevent further recessing of the trench isolation structure 106. An etching process may be used for the partial removal of the dummy gate structure 308. By controlling process time of the etching process, the resulted protection structures 150 may not cover sidewalls of the bottommost sacrificial layers 304′, so as to avoid from hindering removal of the sacrificial layers 304′ in a following channel release step. In some embodiments, top surfaces of the protection structures 150 are positioned below top surfaces of the fin structures 102, on which the bottommost sacrificial layers 304′ are disposed. Also, as described with reference to FIG. 1A and FIG. 1C, portions of the dummy gate dielectric layer 310 in lateral contact with the left portions of the dummy gate electrode 312 (i.e., the protection structures 150) are remained as the dielectric walls 104w. During removal of the dummy gate dielectric layer 310, the protection structures 150 can prevent the portions of the trench isolation structure 106 between the gate spacers 126 from further recessing below the surface 106s.

Referring to FIG. 2 and FIG. 3N, at a step S226, the sacrificial layers 304′ are removed. As a result, the channel structures 110 are released. By disposing the inner spacers 128 at opposite ends of each sacrificial layer 304′ as described with reference to FIG. 3I, etchants for removing the sacrificial layers 304′ may be blocked by the inner spacers 128 from attacking the source/drain structures 130. Therefore, the source/drain structures 130 may be prevent from being damaged during the release of the channel structures 110. Further, as the portions of the trench isolation structure 106 between the gate spacers 126 are shielded by the protection structures 150, the trench isolation structure 106 can be prevented from further recessing below the surface 106s. Moreover, as the protection structures 150 are lower than the bottommost sacrificial layers 304′, removal of these bottommost sacrificial layers 304′ would not be hindered by the protection structures 150.

Referring to FIG. 2 and FIG. 1A, at a step S228, the gate structure 120 is filled in the space between the gate spacers 126. As a result, the gate dielectric layer 122 of the gate structure 120 conformally covers surfaces of the channel structures 110, the fin structures 102, the protection structures 150, the gate spacers 126 and the inner spacers 128 exposed in such space. In addition, the gate electrode 124 of the gate structure 120 is provided on the gate dielectric layer 122, to fill up such space. As described, by disposing the protection structures 150, the trench isolation structure 106 can be prevented from further recessing during removal of the dummy gate structure 308 and the sacrificial layers 304′, thus the gate electrode 120 can be avoided from extending further deeper below the surface 106s of the trench isolation structure 106. Therefore, undesired capacitive coupling between the gate electrode 124 and the source/drain structures 130 can be lowered or even eliminated. Also, in those embodiments where the backside vias 160 described with reference to FIG. 1D are formed, unintended contact between the backside vias 160 and the gate electrode 124 can be prevented as well.

Although not shown, back-end-of-line (BEOL) process may be further performed on the current structure, to out-rout the semiconductor device 100. Moreover, in some embodiments, the resulted structure may be flipped over, and the backside vias 160 described with reference to FIG. 1D are formed into the semiconductor substrate after thinning the semiconductor substrate from backside, for establishing contact with the source/drain structures 130.

As described, the protection structures are remained portions of the dummy gate electrode, and are identical with rest portions of the dummy gate electrode in terms of material. In other embodiments, the protection structures may have surface portions different from rest portions of the dummy gate electrode in terms of material.

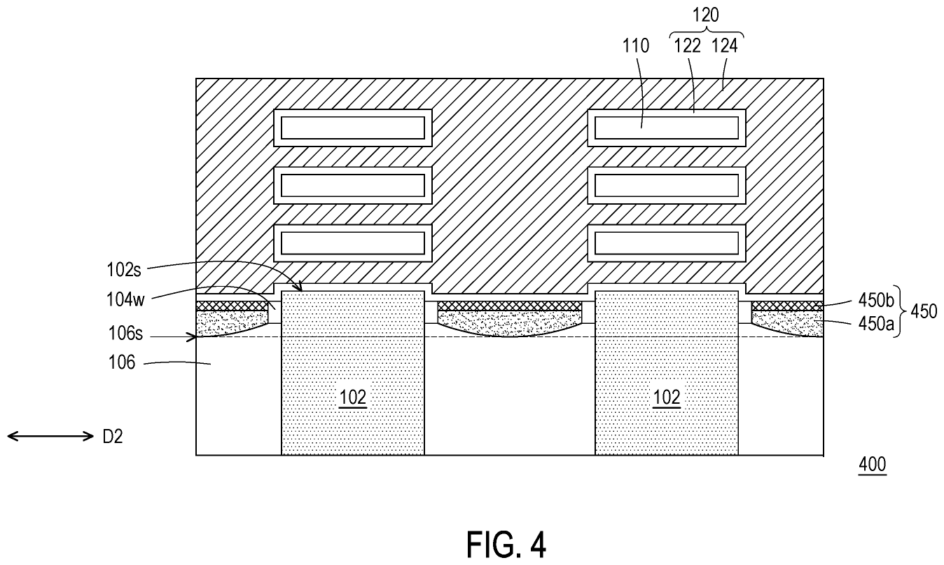

FIG. 4 is a schematic cross-sectional view along a gate structure 120 of a semiconductor device 400, according to some embodiments of the present disclosure.

The semiconductor device 400 is similar to the semiconductor device 100 as described with reference to FIG. 1A through FIG. 1C, except that protection structures 450 of the semiconductor device 400 are formed of at least two different compositions. Specifically, as shown in FIG. 4, each of the protection structures 450 has a body portion 450a and a top portion 450b covering the body portion 450a and lined by the gate dielectric layer 122. Both of the body portion 450a and the top portion 450b include a semiconductor material (e.g., silicon, germanium or silicon germanium), which is used for forming the dummy gate electrode (e.g., the dummy gate electrode 312) being taken placed by the gate electrode 124, and may be formed as amorphous or crystalline (e.g., polycrystalline, single-crystalline or any crystallinity). In addition, the top portion 450b further includes nitrogen. As an example, the body portion 450a may be formed of polysilicon, whereas the top portion 450b may be formed of nitrogen-doped polysilicon or silicon nitride.

In regarding manufacturing, a nitridation process is performed following the partial removal of the dummy gate structure 308 as described with reference to FIG. 3M. As a result, surface portions of the remained dummy gate electrode 312 are nitrided, and form the top portions 450b of the protection structures 450. On the other hand, portions of the remained dummy gate electrode 312 not being nitrided form the body portions 450a of the protection structures 450. As an example, the nitridation process may involve a plasma treatment.

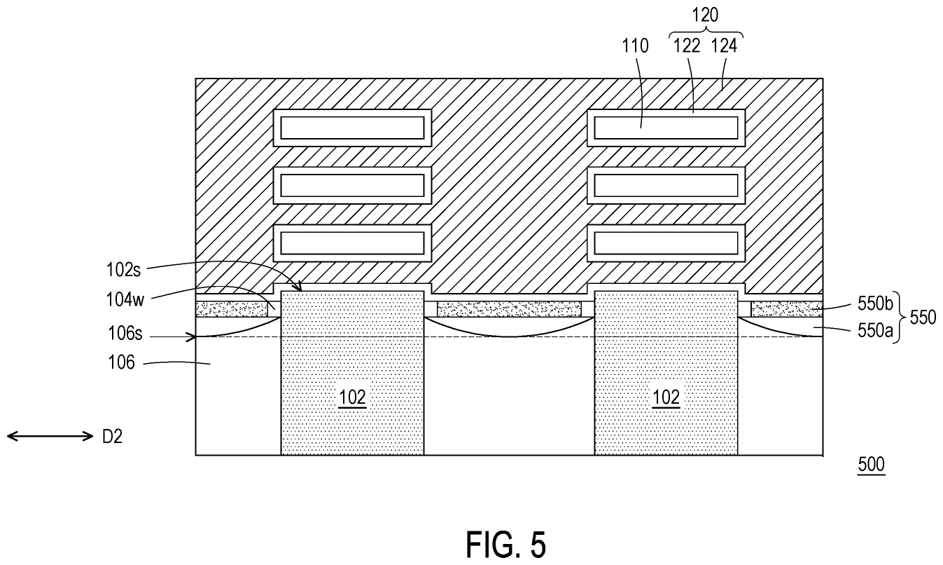

FIG. 5 is a schematic cross-sectional view along a gate structure 120 of a semiconductor device 500, according to some embodiments of the present disclosure.

The semiconductor device 500 is similar to the semiconductor device 100 as described with reference to FIG. 1A through FIG. 1C, except that protection structures 550 of the semiconductor device 500 are respectively a multilayer structure. As shown in FIG. 5, each protection structure 550 includes an insulating layer 550a and a semiconductor layer 550b covering the insulating layer 550a and lined by the gate dielectric layer 122. According to some embodiments, the dielectric walls 104w are disposed on the insulating layers 550a, and in lateral contact with the semiconductor layers 550b. The insulating layer 550a is formed of an insulating material, whereas the semiconductor layer 550b is formed of a semiconductor material. For instance, the insulating material may include silicon nitride or any insulating material with sufficient etching selectivity with the trench isolation structure 106. On the other hand, the semiconductor material may be identical with the semiconductor material for forming the dummy gate electrode (e.g., the dummy gate electrode 312) being taken placed by the gate electrode 124, and may be formed as amorphous or crystalline (e.g., polycrystalline, single-crystalline or any crystallinity).

In regarding manufacturing, an additional deposition process may be performed after the recessing of the trench isolation structure 106 as described with reference to FIG. 3D, to form initial insulating layers selectively covering the trench isolation structure 106. Such initial insulating layers may be patterned to form the insulating layers 550a of the protection structures 550 during formation of the dummy gate structure 308 as described with reference to FIG. 3E. Further, bottom portions of the dummy gate electrode 312 in the dummy gate structure 308 may remain to form the semiconductor layers 550b of the protection structures 550 after the partial removal of the dummy gate structure 308 described with reference to FIG. 3M.

As the protection structures further include surface nitridation portions (i.e., the protection structures 450 described with reference to FIG. 4) or are formed with a combination of insulating and semiconductor layers (i.e., the protection structures 550 described with reference to FIG. 5), etchants used for removing the dummy gate structure 308 and channel release may be more effectively blocked by the protection structures 450, 550. Therefore, it may be more ensured that the trench isolation structure 106 remains covered during the gate replacement and channel release processes, thus prevention of further recessing the trench isolation structure 106 during the gate replacement and channel release processes may be more promised.

Moreover, although not depicted, each of the semiconductor devices 400, 500 may be further formed with the backside vias 160 as described with reference to FIG. 1D. Since further recessing of the trench isolation structure 106 is promised, unintended contact between the gate electrode 124 disposed on the trench isolation structure 106 and the backside vias 106 can be avoided.

Each of the described semiconductor devices 100, 400, 500 may respectively be one of semiconductor devices in a semiconductor chip. In general, a single semiconductor chip includes semiconductor devices with different dimensions. For instance, each of the semiconductor devices 100, 400, 500 may be a semiconductor device in one of standard cells in a semiconductor chip, and such semiconductor chip may further include other semiconductor devices with longer channel length and/or other semiconductor devices with greater channel stack-to-channel stack spacing. Similar manufacturing processes may be used for forming these semiconductor devices with different dimensions. In some cases, all of the semiconductor devices are formed with the protection structures. However, in other cases, only the semiconductor devices in the standard cells are formed with the protection structures.

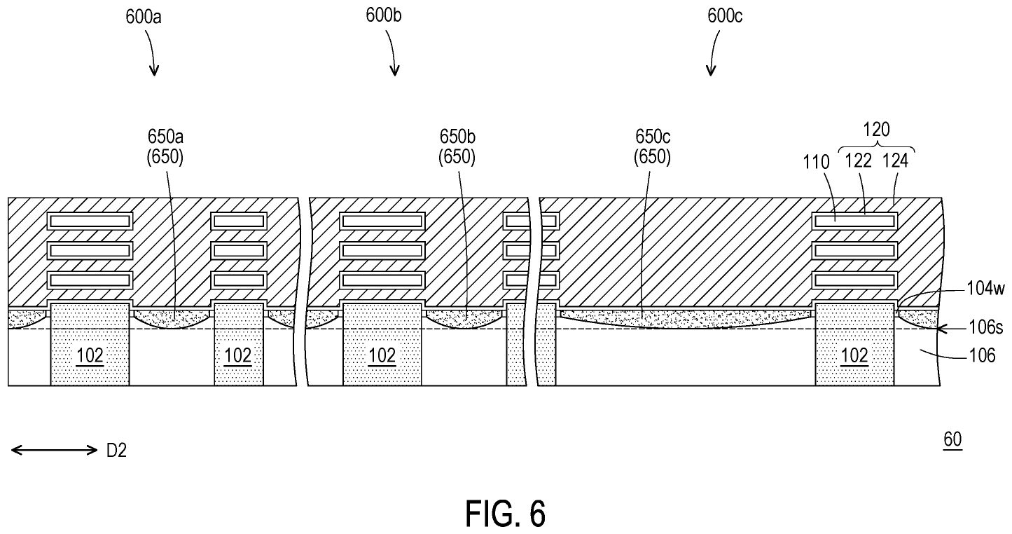

FIG. 6 is a schematic cross-sectional view along gate structures 120 of semiconductor devices 600a, 600b, 600c in a semiconductor chip 60, according to some embodiments of the present disclosure.

Although not completely shown, each of the semiconductor devices 600a, 600b, 600c is similar to the semiconductor device 100 as described with reference to FIG. 1A through FIG. 1C, though the semiconductor devices 600a, 600b, 600c are different with one another in terms of dimensions. Specifically, the semiconductor device 600a is disposed in a standard cell of the semiconductor chip 60, and has a first channel length (i.e., a length of each channel structure 110 along the direction D1 intersected with the direction D2) and a first channel stack-to-channel stack spacing (i.e., a spacing between adjacent stacks of the channel structures 110). On the other hand, the semiconductor device 600b has a second channel length greater than the first channel length. In addition, the semiconductor device 600c has a second channel stack-to-channel stack spacing greater than the first channel stack-to-channel stack spacing.

Despite having different dimensions, the semiconductor devices 600a, 600b, 600c respectively include protection structures 650, which are similar to the protection structures 150 described with reference to FIG. 1A and FIG. 1C in terms of structure, material and crystallinity. As the semiconductor device 600b is greater than the semiconductor device 600a in terms of channel length, the protection structures 650 of the semiconductor device 600b (referred to as protection structures 650b) are longer than the protection structures 650 of the semiconductor device 600a (referred to as protection structures 650a) in terms of length along the direction D1 intersected with the direction D2. In addition, as the semiconductor device 600c is greater than the semiconductor device 600a in terms of channel stack-to-channel stack spacing, the protection structures 650 of the semiconductor device 600c (referred to as protection structures 650c) are wider than the protection structures 650a in terms of width along the direction D2.

According to some embodiments, same manufacturing process is used for forming the semiconductor devices 600a, 600b, 600c. As an example, the process described with reference to FIG. 2 and FIG. 3A through FIG. 3N can be used for all of the semiconductor devices 600a, 600b, 600c. In another example, a nitridation process is further performed after the dummy gate electrode 312 is subjected to removal, and the protection structures 650 may be resulted as similar to the protection structures 450 described with reference to FIG. 4. Further, backside vias (e.g., the backside vias 160 described with reference to FIG. 1D) may be included in some of the semiconductor devices 600a, 600b, 600c. For instance, the semiconductor device 600a may include at least one backside via, whereas a backside via may be absent in each of the semiconductor devices 600b, 600c.

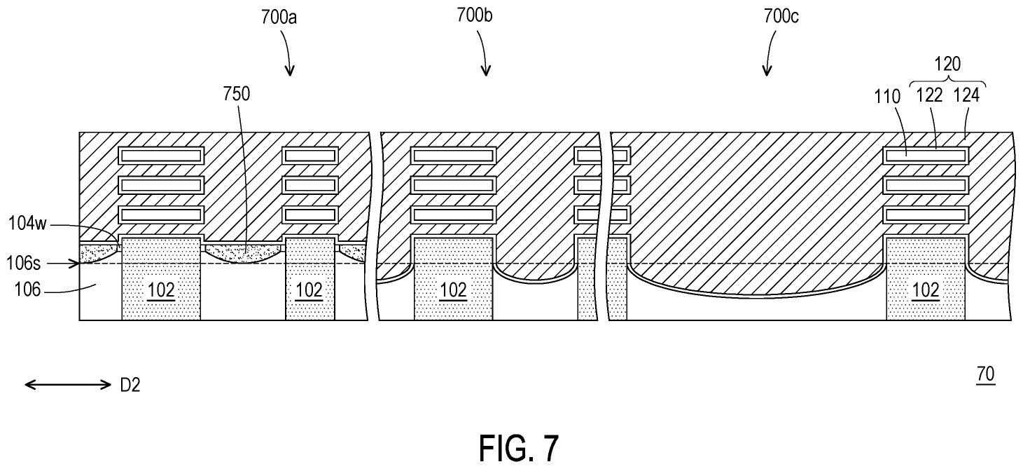

FIG. 7 is a schematic cross-sectional view along gate structures 120 of semiconductor devices 700a, 700b, 700c in a semiconductor chip 70, according to some embodiments of the present disclosure.

As substantially identical with the semiconductor device 600a as described with reference to FIG. 6, the semiconductor device 700a has the first channel length and the first channel stack-to-channel stack spacing, and includes protection structures 750 similar to the protection structures 150 described with reference to FIG. 1A and FIG. 1C, for preventing the trench isolation structure from 106 being further recessed with respect to the surface 106s and thus preventing the gate electrode 124 from extending further deeper than the surface 106s of the trench isolation structure 106.

On the other hand, as similar to the semiconductor device 600b as described with reference to FIG. 6, the semiconductor device 700b has the second channel length greater than the first channel length. However, the semiconductor device 700b does not include any protection structure. Due to absence of protection structures, the trench isolation structure 106 may be further recessed below the surface 106s during removal of the dummy gate structure 308, and the gate electrode 124 may extend deeper below the surface 106s of the trench isolation structure 106. Further, the semiconductor device 700b may not include the dielectric walls 104w, and the gate dielectric layer 122 is in contact with the trench isolation structure 106 without any protection structure and dielectric wall in between.

In addition, as similar to the semiconductor device 600c as described with reference to FIG. 6, the semiconductor device 700c has the second channel stack-to-channel stack spacing greater than the first channel stack-to-channel stack spacing. However, the semiconductor device 700c does not include any protection structure, as similar to the semiconductor device 700b. Therefore, in the semiconductor device 700c, the trench isolation structure 106 may be further recessed below the surface 106s during removal of the dummy gate structure 308, and the gate electrode 124 may extend deeper below the surface 106s of the trench isolation structure 106. Further, the semiconductor device 700c may not include the dielectric walls 104w, and the gate dielectric layer 122 is in contact with the trench isolation structure 106 without any protection structure and dielectric wall in between.

According to some embodiments, same manufacturing process is used for forming the semiconductor devices 700a, 700b, 700c. Owing to dimensional differences between the semiconductor devices 700a, 700b, 700c, bottom portions of the dummy gate electrode 312 in the semiconductor device 700a may be remained to form the protection structures 750, whereas the dummy gate electrodes 312 in the semiconductor devices 700b, 700c are completely removed during gate replacement and channel release.

In some embodiments, the semiconductor device 700a is further formed with backside vias (e.g., the backside vias 160 described with reference to FIG. 1D), while the semiconductor devices 700b, 700c are not. In these embodiments, the protection structures 750 can prevent leakage paths between the source/drain structures 130 and the gate electrode 124 through the backside vias in the semiconductor device 700a. In addition, since the backside vias are absent in the semiconductor devices 700b, 700c, the leakage paths between the source/drain structures 130 and the gate electrode 124 may not be established, even though the gate electrodes 124 of the semiconductor devices 700b, 700c may extend deeper below the surface 106s of the trench isolation structure 106.

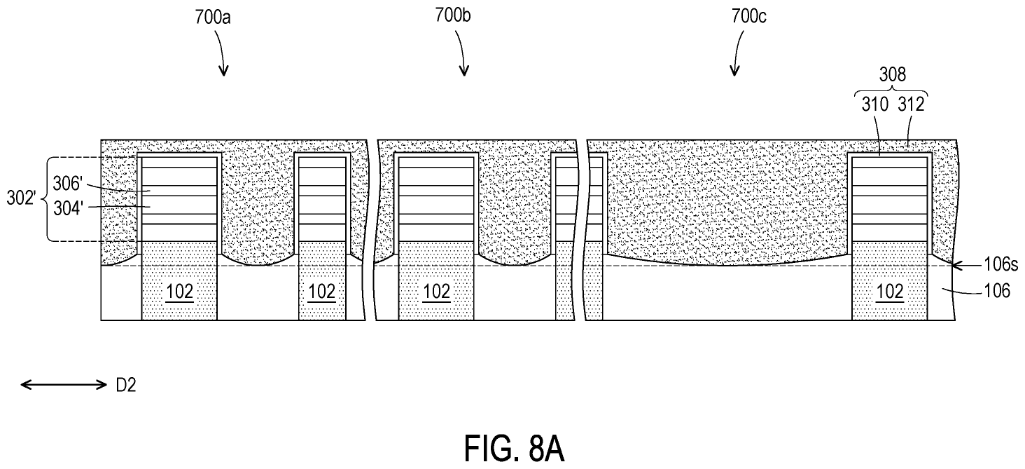

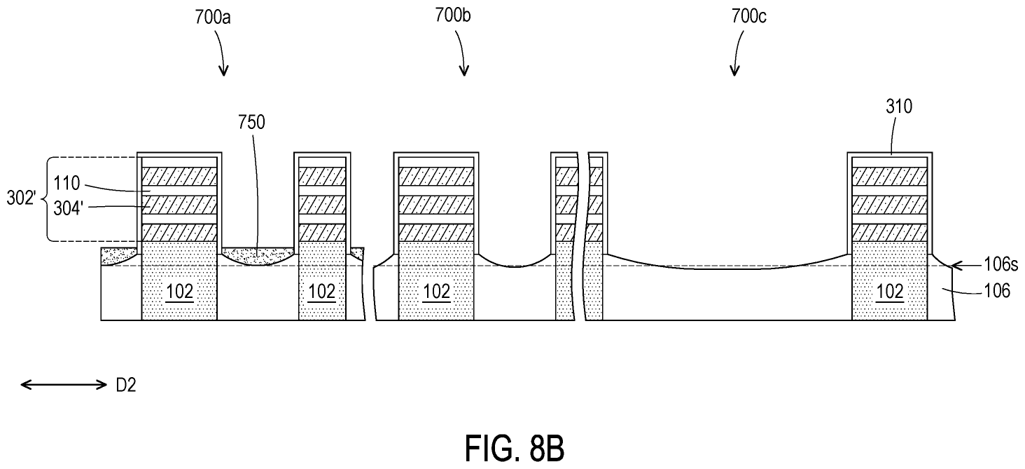

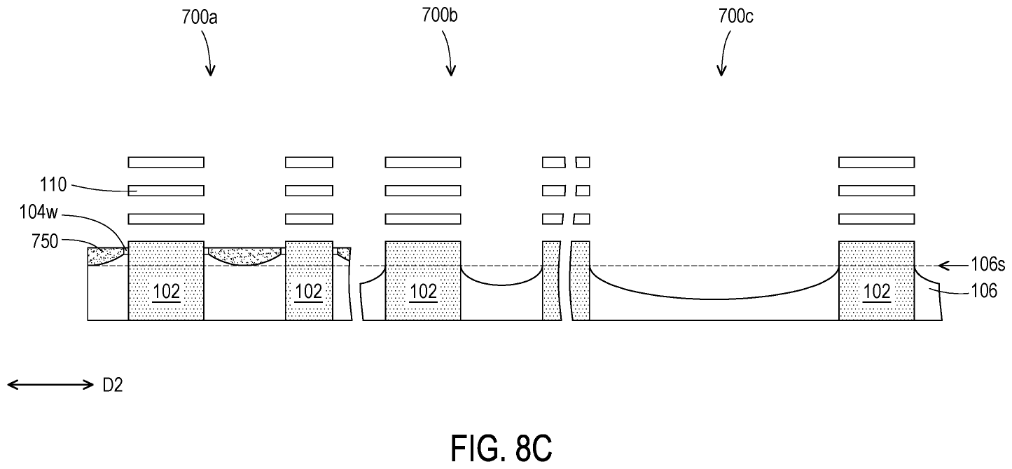

FIG. 8A through FIG. 8C are schematic cross-sectional views illustrating intermediate structures at some stages during manufacturing of the semiconductor chip 70 as shown in FIG. 7, according to some embodiments of the present disclosure.

The manufacturing process for forming each of the semiconductor devices 700a, 700b, 700c is similar to the manufacturing process described with reference to FIG. 2 and FIG. 3A through FIG. 3N. FIG. 8A through FIG. 8C only show steps of removing the dummy gate structure 308 and channel release, other process steps before and after the removal of the dummy gate structure and the channel release can be referred to the process described with reference to FIG. 2 and FIG. 3A through FIG. 3N.

At a stage shown in FIG. 8A, the dummy gate structures 308 for the semiconductor devices 700a, 700b, 700c are formed on the surface 106s of the trench isolation structure 106, and cover the stacking structures 302′ from which the channel layers 306′ will be released to form the channel structures 110 of the semiconductor devices 700a, 700b, 700c. Dummy gate dielectric layers 310 of the dummy gate structures 308 conformally cover the stacking structures 302′, respectively. In addition, the dummy gate electrodes 312 of the dummy gate structures 308 laterally extend on the trench isolation structure 106 and the stacking structures 302′, and cover the dummy gate dielectric layers 310.

At a stage shown in FIG. 8B, the dummy gate electrodes 312 are subjected to removal. An etching process may be used for the removal. Due to dimensional differences between the stacking structures 302′ for the semiconductor devices 700a, 700b, 700c, the dummy gate electrodes 312 may be removed by different amount. Specifically, the stacking structures 302′ for the semiconductor device 700a have the shortest length and shortest spacing, and the dummy gate electrode 312 for the semiconductor device 700a may be removed by fewest amount. As a result, the dummy gate electrode 312 for the semiconductor device 700a is not completely removed, and remained portions of the dummy gate electrode 312 for the semiconductor device 700a form the protection structures 750 of the semiconductor device 700a. On the other hand, the dummy gate electrodes 312 for the semiconductor devices 700b, 700c may be completely removed, and underlying portions of the trench isolation structure 106 are exposed and may be further recessed.

At a stage shown in FIG. 8C, the dummy gate dielectric layers 310 and the sacrificial layers 304′ in the stacking structures 302′ are subjected to removal. Specifically, portions of the dummy gate dielectric layers 310 covering the stacking structures 302′ are removed, whereas portions of the dummy gate dielectric layer 310 in lateral contact with the protection structures 750 may not be exposed, and may remain as the dielectric walls 104w. In addition, the sacrificial layers 304′ are removed, and the channel structures 110 are released. Further, during the removal of the dummy gate dielectric layers 310 and the sacrificial layers 304′, exposed portions of the trench isolation structure 106 may be further recessed to a depth much deeper than the surface 106s. In some embodiments, portions of the trench isolation structure 106 within the semiconductor device 700c are recessed more than portions of the trench isolation structure 106 within the semiconductor device 700b.

As the gate structures 120 are disposed, the semiconductor devices 700a, 700b, 700c can be formed in the semiconductor chip 70. Although not shown, an additional nitridation step can be performed following the removal of the dummy gate electrode 312 shown in FIG. 8B, and the protection structures 750 may be resulted as similar to the protection structures 450 described with reference to FIG. 4. Further, in some embodiments, the semiconductor chip 70 may be flipped over, and backside vias may be formed into the semiconductor device 700a from a backside of the semiconductor chip 70.

As described, same manufacturing process is used for each of the semiconductor devices 700a, 700b, 700c. Alternatively, a process for forming the semiconductor device 700a is slightly different from a process for forming each of the semiconductor devices 700b, 700c.

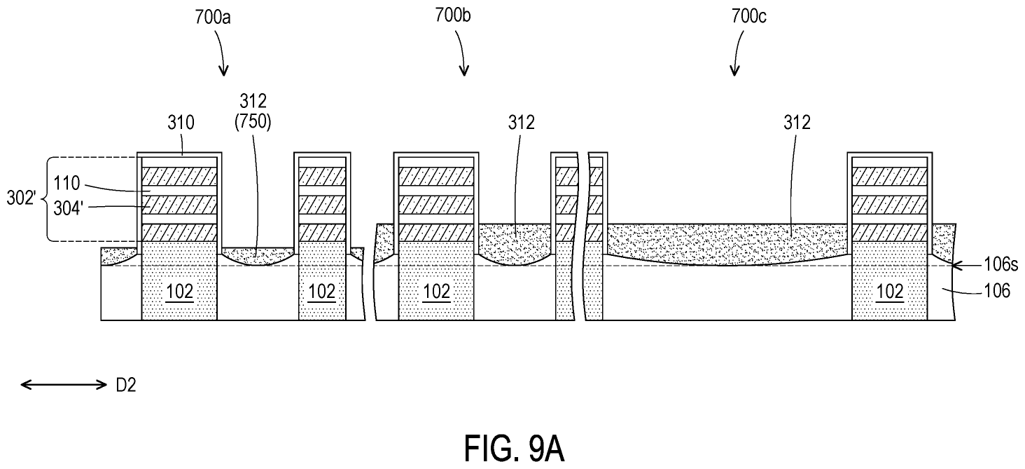

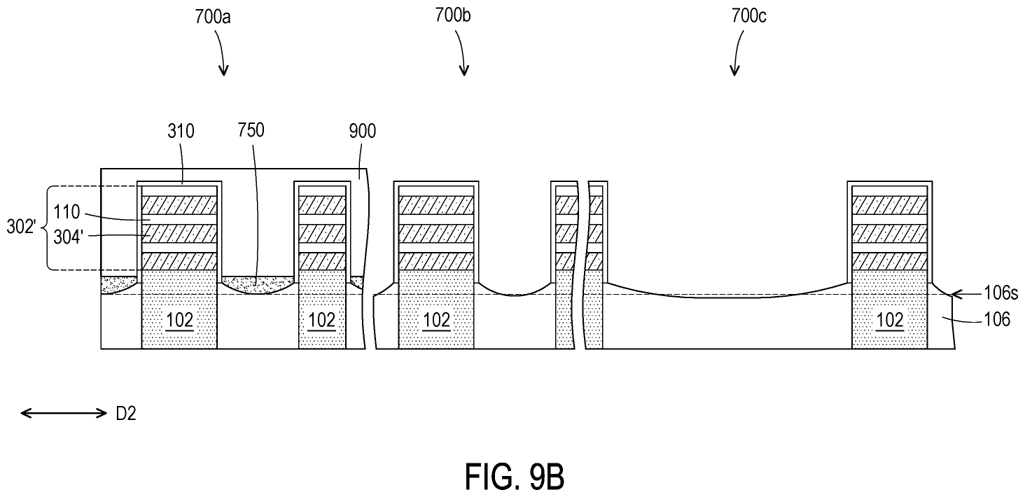

FIG. 9A and FIG. 9B are schematic cross-sectional views illustrating intermediate structures at some stages during manufacturing of the semiconductor chip 70 as shown in FIG. 7, according to alternative embodiments of the present disclosure.

It should be noted that, FIG. 9A and FIG. 9B only show steps for removing the dummy gate electrode 312, other process steps before and after the removal of the dummy gate structure and the channel release can be referred to the process described with reference to FIG. 2 and FIG. 3A through FIG. 3N.

At a stage shown in FIG. 9A, the dummy gate electrodes 312 are subjected to removal. An etching process is used for such removal. Owing to dimensional difference, the dummy gate electrodes 312 for the semiconductor devices 700a, 700b, 700c may be etched away by different amount. Specifically, the dummy gate electrode 312 for the semiconductor device 700a is recessed to a height lower than top surfaces of the fin structures 102, and remained portions of this dummy gate electrode 312 form the protection structures 750. On the other hand, the dummy gate electrodes 312 for the semiconductor devices 700b, 700c are recessed to a height above the top surfaces of the fin structures 102, and remained portions of these dummy gate electrodes 312 are in lateral contact with bottom portions of the stacking structures 302′ within the semiconductor devices 700b, 700c.

At a stage shown in FIG. 9B, the remained portions of the dummy gate electrodes 312 within the semiconductor devices 700b, 700c are selectively removed, to avoid from hindering channel release of the semiconductor devices 700b, 700c. Specifically, a mask pattern 900 is formed to cover the current intermediate structure of the semiconductor device 700a, while exposing the current intermediate structures of the semiconductor devices 700b, 700c. In this way, the remained portions of the dummy gate electrodes 312 within the semiconductor devices 700b, 700c are exposed. By performing a further etching process, these remained portions of the dummy gate electrodes 312 can be completely removed, and portions of the trench isolation structure 106 lying below are exposed. In certain cases, the exposed portions of the trench isolation structure 106 may be slightly recessed in the current step.

Thereafter, the mask pattern 900 is removed. In addition, the dummy gate dielectric layers 310 and the sacrificial layers 304′ in the stacking structures 302′ within the semiconductor devices 700a, 700b, 700c are subjected to removal. The resulted structure may be substantially identical to the structure described with reference to FIG. 8C. As the gate structures 120 are disposed, the semiconductor devices 700a, 700b, 700c can be formed in the semiconductor chip 70.

Although not shown, an additional nitridation step can be performed following the removal of the dummy gate electrode 312, and the protection structures 750 may be resulted as similar to the protection structures 450 described with reference to FIG. 4. Further, in some embodiments, the semiconductor chip 70 may be flipped over, and backside vias may be formed into the semiconductor device 700a from a backside of the semiconductor chip 70.

As described, the semiconductor devices in a standard cell of a semiconductor chip are formed with the protection structures, whereas other semiconductor devices in the semiconductor chip may or may not be formed with the protection structures. In general, a semiconductor chip may include rows of standard cells, and some of the standard cells may be different from others in terms of channel width and/or channel stack-to-channel stack spacing. As a result, the protection structures in some of the standard cells may be thicker or thinner than the protection structures in other standard cells. In certain cases, the semiconductor devices in some standard cells may not include the protection structures.

As above, a semiconductor device, a semiconductor chip and manufacturing methods for forming the semiconductor device and the semiconductor chip are provided. The semiconductor device includes channel structures; a gate structure intersecting and wrapping around the channel structures; and source/drain structures at opposite bounds of the channel structures. In addition, the gate structure is spaced apart from an underlying trench isolation structure via protection structures. By disposing the protection structures, the trench isolation structure can be prevented from further recessing during gate replacement and channel release. Accordingly, the gate structure can be avoided from extending to a greater depth. Therefore, undesired capacitive coupling between the gate structure and the source/drain structures can be effectively lowered. In some embodiments, backside via(s) may be further formed to the source/drain structure(s) from backside of the semiconductor device. As the gate structure can be prevented from extending further deeper, it can be ensured that the gate structure is vertically spaced apart from the backside via(s). In this way, unintended contact between the gate structure and the backside via(s) can be avoided.

In an aspect of the present disclosure, a semiconductor device is provided. The semiconductor device comprises: channel structures, vertically spaced apart from one another; a gate structure, intersecting the channel structures and wrapping around each of the channel structures; source/drain structures, in lateral contact with the channel structures from opposite sides of the channel structures; and protection structures, separately disposed along a bottom surface of the gate structure, wherein the channel structures are located between the protection structures, and the protection structures comprise a semiconductor material.

In another aspect of the present disclosure, a semiconductor device is provided. The semiconductor device comprises: a semiconductor substrate, with a surface fin structure; a trench isolation structure, laterally surrounding the fin structure; channel structures, vertically spaced apart from one another over the fin structure, and extending along the fin structure; a gate structure, intersecting and wrapping around the channel structures; source/drain structures, in lateral contact with the channel structures from opposite sides of the channel structures; and protection structures, separately disposed along a bottom surface of the gate structures to separate the gate structure from the trench isolation structure, and comprising a semiconductor material.

In yet another aspect of the present disclosure, a manufacturing method of a semiconductor device is provided. The method comprises: forming a stacking structure over and along a surface fin structure of a semiconductor substrate, wherein the stacking structure comprises alternately stacked channel layers and sacrificial layers; forming a trench isolation structure to laterally surround the fin structure; forming a dummy gate structure on the trench isolation structure and the stacking structure, wherein the dummy gate structure intersects and covers the stacking structure; removing portions of the stacking structure extending at opposite sides of the dummy gate structure; forming source/drain structures at the opposite sides of the dummy gate structure; subjecting the dummy gate structure to removal, to expose the stacking structure, wherein bottom portions of the dummy gate structure are remained on the trench isolation structure; removing the sacrificial layers, to release the channel layers; and forming a gate structure to wrap around the channel layers, wherein the gate structure is vertically spaced apart from the trench isolation structure via the remained bottom portions of the dummy gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
channel structures, vertically spaced apart from one another;
a gate structure, intersecting the channel structures and wrapping around each of the channel structures;
source/drain structures, in lateral contact with the channel structures from opposite sides of the channel structures; and
protection structures, separately disposed along a bottom surface of the gate structure, wherein the channel structures are located between the protection structures, and the protection structures comprise a semiconductor material.

2. The semiconductor device according to claim 1, further comprising:
gate spacers, covering opposite sidewalls of the gate structure, wherein the protection structures are located between the gate spacers.

3. The semiconductor device according to claim 1, wherein the channel structures extend along an underlying fin structure, the fin structure is located between the protection structures, and top surfaces of the protection structures are lower than a top surface of the fin structure.

4. The semiconductor device according to claim 3, wherein the protection structures are in lateral contact with the fin structure via dielectric walls.

5. The semiconductor device according to claim 1, wherein the gate structure comprises:
a gate dielectric layer, covering each of the channel structures, and extending along opposite sidewalls and a bottom surface of the gate structure; and
a gate electrode, in contact with the channel structure and the protection structures through the gate dielectric layer.

6. The semiconductor device according to claim 1, wherein the semiconductor material is doped with nitrogen in a surface portion of each protection structure.

7. The semiconductor device according to claim 1, wherein the protection structures respectively comprise an insulating layer formed of an insulating material and a semiconductor layer covering the insulating layer and formed of the semiconductor material.

8. The semiconductor device according to claim 1, further comprising:
a backside via, extending to one of the source/drain structures from a backside of the semiconductor device, wherein the gate structure is vertically spaced apart from the backside via.

9. A semiconductor device, comprising:
a semiconductor substrate, with a surface fin structure;
a trench isolation structure, laterally surrounding the fin structure;
channel structures, vertically spaced apart from one another over the fin structure, and extending along the fin structure;
a gate structure, intersecting and wrapping around the channel structures;
source/drain structures, in lateral contact with the channel structures from opposite sides of the channel structures; and
protection structures, separately disposed along a bottom surface of the gate structures to separate the gate structure from the trench isolation structure, and comprising a semiconductor material.

10. The semiconductor device according to claim 9, wherein the fin structure protrudes with respect to the trench isolation structure, and top surfaces of the protection structures are lower than a top surface of the fin structure.

11. The semiconductor device according to claim 9, further comprising:
gate spacers, separating the gate structure from the source/drain structures, wherein the protection structures are confined in between the gate spacers.

12. The semiconductor device according to claim 9, wherein the fin structure is in lateral contact with the protection structures via dielectric walls.

13. The semiconductor device according to claim 12, wherein the protection structures and the dielectric walls are covered by a gate dielectric layer of the gate structure.

14. A manufacturing method of a semiconductor device, comprising:
forming a stacking structure over and along a surface fin structure of a semiconductor substrate, wherein the stacking structure comprises alternately stacked channel layers and sacrificial layers;
forming a trench isolation structure to laterally surround the fin structure;
forming a dummy gate structure on the trench isolation structure and the stacking structure, wherein the dummy gate structure intersects and covers the stacking structure;
removing portions of the stacking structure extending at opposite sides of the dummy gate structure;
forming source/drain structures at the opposite sides of the dummy gate structure;
subjecting the dummy gate structure to removal, to expose the stacking structure, wherein bottom portions of the dummy gate structure are remained on the trench isolation structure;
removing the sacrificial layers, to release the channel layers; and
forming a gate structure to wrap around the channel layers, wherein the gate structure is vertically spaced apart from the trench isolation structure via the remained bottom portions of the dummy gate structure.

15. The manufacturing method of the semiconductor device according to claim 14, wherein the remained bottom portions of the dummy gate structure prevent the trench isolation structure from further recessing during removal of the dummy gate structure and release of the channel layers.

16. The manufacturing method of the semiconductor device according to claim 14, wherein top surfaces of the remained bottom portions of the dummy gate structure are lower than a top surface of the fin structure.

17. The manufacturing method of the semiconductor device according to claim 14, wherein crystallinity of the remained bottom portions of the dummy gate structure is substantially identical with crystallinity of rest portions of the dummy gate structure.

18. The manufacturing method of the semiconductor device according to claim 14, wherein crystallinity of the remained bottom portions of the dummy gate structure is lower than crystallinity of rest portions of the dummy gate structure.

19. The manufacturing method of the semiconductor device according to claim 14, further comprising:
performing a nitridation process to the remained bottom portions of the dummy gate structure before formation of the gate structure.

20. The manufacturing method of the semiconductor device according to claim 14, further comprising:
forming insulating layers between the dummy gate structure and the trench isolation structure, such that the insulating layers and the bottom portions of the dummy gate structure remain after the removal of the dummy gate structure.
